(19) United States
(12) Patent Application Publication
(10) Pub. No.: US 2011/0193639 A1
(43) Pub. Date: Aug. 11, 2011

(54) Pure-Silicon Digital Oscillator

(75) Inventors: Ta-I LIU, Taipei (TW); Chung-Chih Tung, Taipei (TW)

(73) Assignee: Ta-I LIU

(21) Appl. No.: 12/704,195

(22) Filed: Feb. 11, 2010

(51) Int. Cl. H03L 9/00

(52) U.S. Cl. 331/1 A

(57) ABSTRACT

A pure-silicon digital oscillator includes a baseband generator for generating a standard baseband, and a clock pulse monitoring and modulating circuit for performing a frequency calibration to the standard baseband to produce a calibrated baseband, while storing an error value produced during the calibration into a data storage device, such that a frequency generator can generate an output frequency according to a numerical value of the calibrated baseband. After the output frequency is processed by a digital signal processing to form a digital output frequency to be inputted into a square wave generator, the square wave generator outputs a higher digital frequency according to the numerical value of the digital output frequency, and the higher digital frequency is provided for a digital power supply control device to drive currents and modulate voltages.

### BACKGROUND OF THE INVENTION

1. Field of the Invention

The present invention relates to a pure-silicon digital oscillator, and more particularly to a pure-silicon digital oscillator capable of performing a frequency modulation automatically in order to prevent frequency jitters of an output frequency.

2. Description of Related Art

In the field of communications, a frequency close to the frequency of a clock pulse signal must be used at both data transmitting end and data receiving end to assure a correct data transmission. Such frequency requirement varies with different application areas. For example, the USB specification defines a maximum clock tolerance of ±500 ppm for a high speed mode and ±2,500 ppm for a full speed mode. In general, the higher data transmission rate, the stricter is the error requirement. To comply with the high-precision requirement, a quartz oscillator with a higher precision is generally used at both transmitting and receiving ends.

However, conventional quartz oscillators and other high-precision oscillators incur a higher cost and come with a high installation failure rate, and thus they cannot be attached to a circuit board by a surface mount technology (SMT) easily and usually result in a higher level of difficulty for the manufacture as well as a higher manufacturing cost. Obviously, the conventional oscillators require improvements.

### SUMMARY OF THE INVENTION

In view of the aforementioned shortcomings of the conventional quartz oscillator, the inventor of the present invention based on years of experience in the related industry to conduct extensive researches and experiments, and finally developed a pure-silicon digital oscillator in accordance with the present invention to overcome the shortcomings of the prior art.

Therefore, it is a primary objective of the present invention to provide a pure-silicon digital oscillator that adopts a semiconductor pure-silicon circuit as an oscillator circuit to overcome each of the aforementioned shortcomings of the conventional quartz oscillator.

Another objective of the present invention is to provide a pure-silicon digital oscillator capable of performing a frequency modulation automatically to prevent frequency jitters of an output frequency.

To achieve the foregoing objectives, the present invention has a baseband generator for generating a standard baseband that can be used for a frequency calibration by a clock pulse monitoring and modulating circuit to calibrate and produce a calibrated baseband, while storing an error value produced during the calibration into a data storage device, such that a frequency generator can generate an output frequency according to a numerical value of the calibrated baseband. After the output frequency is processed by a digital signal processor to form a digital output frequency to be inputted into a square wave generator, the square wave generator outputs a higher digital frequency according to the numerical value of the digital output frequency, wherein the higher digital frequency is provided for a digital power supply control device to drive currents and modulate voltages. With the frequency modulation and the digital processing, the digital frequency outputted by the square wave generator is free of frequency jitters, and the digital power supply control device can achieve a correct voltage modulation.

### BRIEF DESCRIPTION OF THE DRAWINGS

The invention, as well as its many advantages, may be further understood by the following detailed description and drawings in which:

FIG. 1 is a block diagram of a structure of the present invention; and

FIG. 2 is a schematic view of a frequency modulation of the present invention.

### DETAILED DESCRIPTION OF THE INVENTION

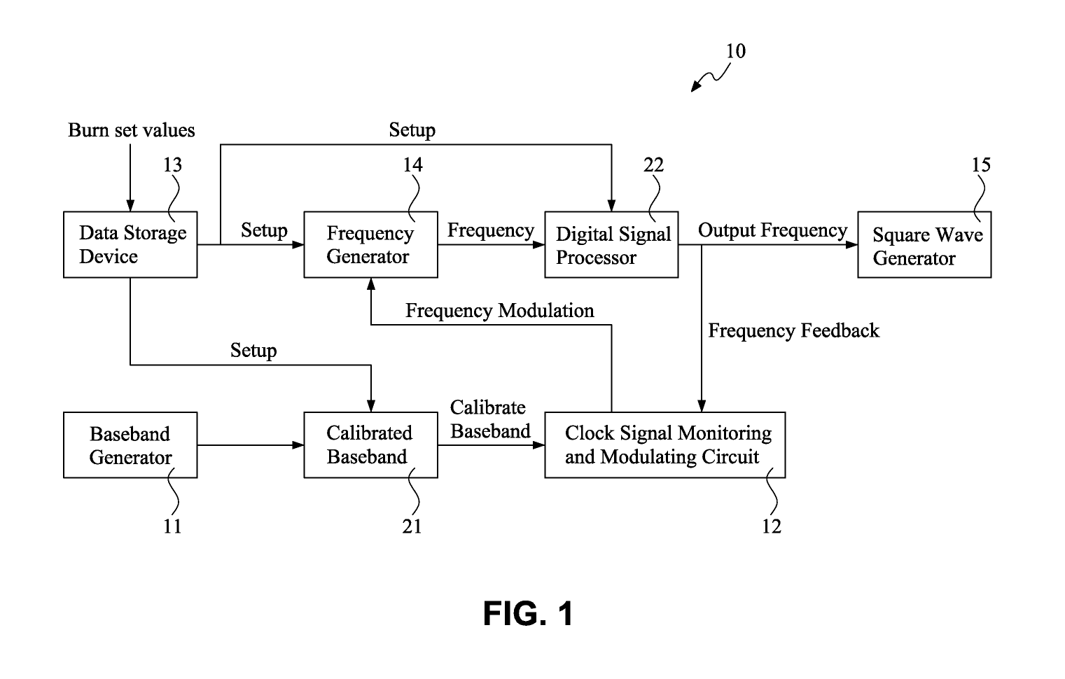

With reference to FIG. 1 for a pure-silicon digital oscillator in accordance with the present invention, the pure-silicon digital oscillator 10 comprises a baseband generator 11, a clock pulse monitoring and modulating circuit 12, a data storage device 13, a frequency generator 14 and a square wave generator 15, wherein the baseband generator 11 is provided for generating a standard fundamental oscillation frequency; the clock pulse monitoring and modulating circuit 12 is provided for modulating and calibrating the standard fundamental oscillation frequency; the data storage device 13 is provided for storing an error value produced when modulating and calibrating the standard fundamental oscillation frequency; the frequency generator 14 is provided for generating an output frequency according to a numerical value of a calibrated baseband; and the square wave generator 15 is provided for generating a higher digital frequency according to the numerical value of the digital output frequency.

During use, the baseband generator 11 generates a standard fundamental oscillation frequency, so that the clock pulse monitoring and modulating circuit 12 can perform a frequency calibration to the standard fundamental oscillation frequency to produce a calibrated baseband 21, while storing an error value produced during the calibration into the data storage device 13, such that the frequency generator 14 can generate an output frequency according to the numerical value of the calibrated baseband 21. After the output frequency is processed by a digital signal processor 22, a digital output frequency is produced and inputted into the square wave generator 15, so that the square wave generator 15 can output a higher digital frequency according to the numerical value of the digital output frequency, and the higher digital frequency is provided for a digital power supply control device (not shown in the figure) to drive currents and modulate voltages.

With the frequency modulation and the digital processing, the digital frequency outputted by the square wave generator 15 is free of frequency jitters, and the digital power supply control device can achieve a correct voltage modulation.

In FIG. 1, the data storage device 13 is an electronic erasable programmable read only memory (EEPROM) for storing an error value produced during the modulation and calibration of the standard fundamental oscillation frequency, and the error value is provided as a reference for manufacturing the next pure-silicon digital oscillator in order to avoid possible errors produced during the manufacturing process of the next pure-silicon digital oscillator. In the meantime, setup values of the frequency modulation and digital processing can be burned or stored into the data storage device 13 and used for setting up the frequency modulation and the digital signal processing.

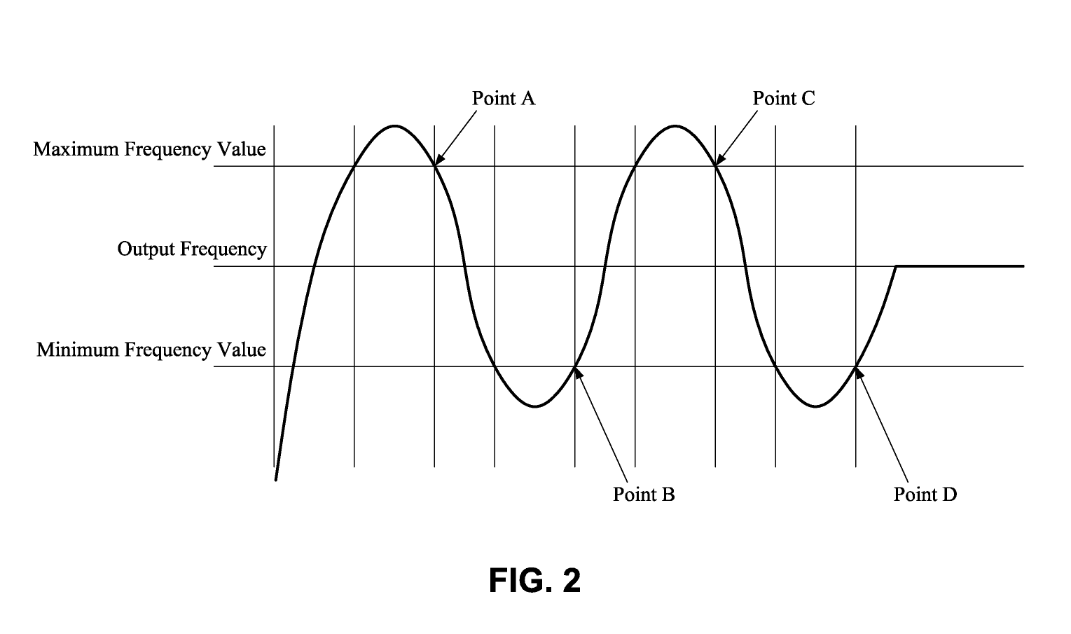

With reference to FIG. 2, if the clock pulse monitoring and modulating circuit 12 is used for a frequency calibration, a feedback frequency is calculated after the baseband is calibrated. If the drift control of the feedback frequency reaches its maximum or minimum value, the clock pulse monitoring and modulating circuit 12 will notice the frequency generator 14 to carry out a modulation. On the other hand, no action will be taken if the frequency falls within an acceptable range. In FIG. 2, Points A and C exceeding the maximum value and Points B and D exceeding the minimum value will be eliminated, and the values remained within the acceptable range are averaged to obtain the frequency, so as to achieve the effect of a constant frequency output.

In summation of the description above, the foregoing standard baseband is used for generating a calibrated baseband, which is obtained at a standard time after the feedback frequency is calculated. In the standard baseband, there is a temperature deviation issue, and thus the digital processing method is provided for processing the produced baseband, such that the temperature deviation and/or other issues will not result in a frequency error (wherein the standard frequency-temperature error value remains below 15000 PPM), and such frequency error will be stored back into the EEPROM during a production testing procedure, so that an error occurred during the production process can be avoided.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A pure-silicon digital oscillator, comprising:
a baseband generator, for generating a standard fundamental oscillation frequency;
a clock pulse monitoring and modulating circuit, for modulating and calibrating the standard fundamental oscillation frequency;
a data storage device, for storing an error value produced when the standard fundamental oscillation frequency is modulated and calibrated;
a frequency generator, for generating an output frequency according to a numerical value of a calibrated baseband;
a square wave generator, for outputting a higher digital frequency according to the numerical value of the digital output frequency;
wherein the baseband generator generates a standard fundamental oscillation frequency, and the clock pulse monitoring and modulating circuit performs a frequency calibration to the standard fundamental oscillation frequency to produce a calibrated baseband, while storing an error value produced during the calibration into the data storage device, and the frequency generator generates an output frequency according to a numerical value of the calibrated baseband, and after the output frequency is processed by a digital signal processor to produce a digital output frequency to be inputted into the square wave generator, the square wave generator outputs a higher digital frequency according to the numerical value of the digital output frequency.

2. The pure-silicon digital oscillator of claim 1, wherein the data storage device is an electronic erasable programmable read only memory (EEPROM).

3. The pure-silicon digital oscillator of claim 2, wherein the data storage device burns and stores set values of a frequency modulation and a digital processing, and the set values are used for setting the frequency modulation and the digital processing.

4. The pure-silicon digital oscillator of claim 1, wherein the clock pulse monitoring and modulating circuit calculates the feedback frequency after the calibrated baseband is obtained, and if the feedback frequency drift control reaches its maximum or minimum value, then the clock pulse monitoring and modulating circuit will notice the frequency generator to carry out a modulation, or else no action will be taken.
